(19) United States
(12) Patent Application Publication
(10) Pub. No.: US 2024/0397228 A1
(43) Pub. Date: Nov. 28, 2024

(54) ELECTRONIC DEVICE AND METHOD

(71) Applicant: Sony Group Corporation, Tokyo (JP)

(72) Inventors: Piergiorgio SARTOR, Stuttgart (DE); Mattia ROSSI, Stuttgart (DE); Diederik Paul MOEYS, Stuttgart (DE)

(73) Assignee: Sony Group Corporation, Tokyo (JP)

(21) Appl. No.: 18/699,324

(22) PCT Filed: Oct. 19, 2022
(86) PCT No.: PCT/EP2022/079112

§ 371 Date: Apr. 8, 2024

(30) Foreign Application Priority Data
Oct. 27, 2021 (EP) 21205045.4

(51) Int. Cl. H04N 25/77; G01S 7/4863; G01S 17/894; H04N 25/47

(52) U.S. Cl. CPC H04N 25/77; G01S 7/4863; G01S 17/894; H04N 25/47

(57) ABSTRACT

An electronic device comprising circuitry configured to determine times that pass between photon arrivals at a pixel of an imaging sensor or within larger areas of the imaging sensor, and to convert these times into intensity signals.

### TECHNICAL FIELD

The present disclosure generally pertains to the field of imaging, and in particular to devices and methods for multi-modal image capturing.

### TECHNICAL BACKGROUND

Multi-modal image sensors are more and more common in order to solve several problems which cannot be addressed with simple grayscale or RGB image sensors. The usual trade-off is represented by the number of sensing modalities, for example the number of color channels vs. the single channel resolution. Multi-modality requires a trade-off between the number of modalities and their resolution. The more modalities are required, the more pixels need to be allocated for different purposes. There exist certain possibilities to bring back the original resolution, but these methods are failing when too many modalities are considered, as the information become too sparse to obtain a proper reconstruction.

The generated image data is output to a processing unit for image processing and depth information generation.

Although there exist techniques for setting the configuration of a ToF system, it is generally desirable to improve these existing techniques.

### SUMMARY

According to a first aspect, the disclosure provides an electronic device comprising circuitry configured to determine times that pass between photon arrivals at a pixel of an imaging sensor or within larger areas of the imaging sensor, and to convert these times into intensity signals.

According to a further aspect, the disclosure provides a method comprising determining times that pass between photon arrivals at a pixel of an imaging sensor or within larger areas of the imaging sensor, and to convert these times into intensity signals.

According to a further aspect, the disclosure provides a computer program comprising instructions which are configured to, when executed on a processor, perform determining times that pass between photon arrivals at a pixel of an imaging sensor or within larger areas of the imaging sensor, and to convert these times into intensity signals.

Further aspects are set forth in the dependent claims, the following description, and the drawings.

### BRIEF DESCRIPTION OF THE DRAWINGS

Embodiments are explained by way of example with respect to the accompanying drawings, in which:

FIG. 1 schematically shows the operation principle of a SPAD photodiode. A SPAD is an avalanche photodiode (APD) that works in a voltage range V beyond the negative breakdown voltage V_{BD};

FIG. 2 schematically provides an example of a process of determining a pixel value according to a “photon counting” approach;

FIG. 3 schematically shows a cross-section of an exemplifying super-pixel sensor;

FIG. 4 schematically shows a process of determining a pixel value of a SPAD pixel according to a principle of determining photon arrival times;

FIG. 5a schematically provides an example of a process of determining an event according to a principle of the embodiments;

FIG. 5b schematically provides another example of a process of determining an event according to a principle of the embodiments;

FIG. 6 schematically provides an example of a process of determining a pixel value based on sensor saturation;

FIG. 7 schematically provides an example of a process of determining a pixel value that is based on per pixel wrap-around counting,

FIG. 8 provides a block diagram that schematically describes an implementation of the process described in FIG. 5b using a global counter (timer) and per pixel memories for storing timer values;

FIG. 9 provides a block diagram that schematically describes an implementation of the process described in FIG. 5b using a global counter (timer) and per pixel wrap-around counters;

FIG. 10 provides a block diagram that schematically describes an alternative implementation using a global counter (timer) and a saturation counter;

FIG. 11 shows an example of processing performed in processing block for the processing of photon arrival times;

FIG. 12 schematically describes an embodiment of an electronic device that can implement the processes of the embodiments described above;

FIGS. 13a, b, c show in a diagram the measured light intensity over the normalized light intensity:

FIG. 14a shows a simulated reference image, a simulated reconstructed image and a simulated error image for an average of 10 photons arrival times, taking arrival time of 10 photons per pixel;

FIG. 14b shows a simulated reference image, a simulated reconstructed image and a simulated error image for an average of 100 photons arrival times, taking arrival time of 100 photons per pixel;

FIG. 14c shows a simulated reference image, a simulated reconstructed image and a simulated error image for an average of 1000 photons arrival times, taking arrival time of 10 photons per pixel;

FIG. 15 shows simulations of an original image, an output image, a corrected image, an output error, and a corrected error for filtered arrival times for 10000 clock cycles with 1^{st} order IIR and correction; and

FIG. 16 shows simulations of an original image, an output image, a corrected image, an output error, and a corrected error for average arrival times for 10000 clock cycles with correction.

### DETAILED DESCRIPTION OF EMBODIMENTS

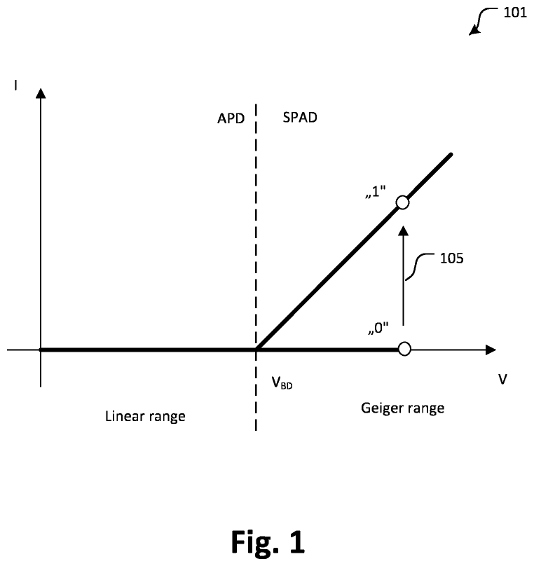

Before a detailed description of the embodiments under reference of FIG. 1 to Fig. . . . , general explanations are made.

The embodiments describe an electronic device comprising circuitry configured to determine times that pass between photon arrivals at a pixel of an imaging sensor or within larger areas of the imaging sensor, and to convert these times into intensity signals.

The electronic device may be a camera device or an imaging device, or the like.

Circuitry may include a processor, a memory (RAM, ROM or the like), a storage, input means (mouse, keyboard, camera, etc.), output means (display (e.g. liquid crystal, (organic) light emitting diode, etc.), loudspeakers, etc., a (wireless) interface, etc., as it is generally known for electronic devices (computers, smartphones, etc.). Moreover, it may include sensors for sensing still image or video image data (image sensor, camera sensor, video sensor, etc.), for sensing a fingerprint, for sensing environmental parameters (e.g. radar, humidity, light, temperature), etc.

Intensity signals may be any pixel values that represent the intensity of light falling onto the sensor.

The intensity per pixel may for example be measured by counting photons arrivals in the time domain.

Determining the times that pass between photon arrivals at a pixel of an imaging sensor or within larger areas of the imaging sensor may for example comprise counting events produced by a counter or measuring time with a timer.

The circuitry may be configured to determine photon arrival times at the pixel of the imaging sensor.

For example, the circuitry may be configured to determine the times that pass between consecutive photon arrivals at a pixel or within larger areas of the imaging sensor.

According to some embodiments, the circuitry is configured to perform processing of arrival times.

According to some embodiments, the circuitry is configured to perform arrival time averaging.

According to some embodiments, the circuitry is configured to perform arrival time averaging applying an LP filter.

According to some embodiments, the circuitry is configured to perform determining of events.

According to some embodiments, the circuitry is configured to determine derivatives of arrival time averages.

According to some embodiments, the circuitry is configured to determine derivatives of arrival times.

According to some embodiments, the circuitry is configured to determine averages of derivatives of arrival times.

According to some embodiments, the circuitry is configured to determine intensity signals for the pixels of the imaging sensor based on sensor saturation.

According to some embodiments, the circuitry is configured to determine intensity signals for the pixel of the imaging sensor based on per pixel wrap-around counting.

The electronic device may comprise a global counter configured to measure the time for the whole sensor.

The electronic device may comprise a global counter and per pixel memories for storing timer values.

The electronic device may comprise a global counter and per pixel wrap-around counters.

The electronic device may comprise a global counter and a saturation counter.

The imaging sensor may use SPAD technologies or similar technologies. Single photon avalanche diodes (SPADs) are particularly suitable for direct time-of-flight measurements due to their ability to detect single photons and their temporal resolution in the picosecond range.

The imaging sensor may be a giga-pixel imaging sensor.

The pixels may be synchronous pixels. For example, in synchronous pixels, events are in general not related to a global timing but may happen individually at each pixel, i.e. independently of the generation of events in other pixels of the sensor.

The imaging sensor may be configured to support different modalities.

The imaging sensor may for example be configured to be applied in Event-Based Vision Sensors (EVS).

The embodiments also disclose a method comprising determining times that pass between photon arrivals at a pixel of an imaging sensor or within larger areas of the imaging sensor, and to convert these times into intensity signals.

The embodiments also disclose a computer program comprising instructions which are configured to, when executed on a processor, perform the method described here.

In some embodiments, also a non-transitory computer-readable recording medium is provided that stores therein a computer program product, which, when executed by a processor, such as the processor described above, causes the methods described herein to be performed.

FIG. 1 schematically shows the operation principle of a SPAD photodiode. A SPAD is an avalanche photodiode (APD) that works in a voltage range V beyond the negative breakdown voltage V_{BD}. In this range (indicated by SPAD in FIG. 1), an electron-hole pair produced by a single photon triggers an avalanche effect, as indicated by arrow 105. The avalanche effect results in a macroscopic current I flowing through the diode.

It is expected that SPAD-based image sensors will allow giga-pixel resolution, possibly using NAPD (Nano-multiplication-region Avalanche Photo Diode) or a variation of this concept such as described by Kang L. Wang et al in “Towards Ultimate Single Photon Counting Imaging CMOS Applications”, Workshop for Astronomy and Space Sciences, Jan. 5 and 6, 2011, or by Xinyu Zheng et al in “Modeling and Fabrication of a Nano-multiplication-region Avalanche Photodiode”, January 2007, esto.nasa.gov. Usually, the purpose of such a high number of pixels is to achieve the so called “digital film”, where the spatial counting of photons arrivals within an area of the sensor delivers the final pixel value. If the photons are counted temporally, rather than spatially, then the high pixel count of the image sensor can be used to increase the capturing modalities. This means that multi/hyper-spectral acquisition, polarization and even ToF capabilities could be integrated into the same single sensor.

A SPAD pixel is a binary device: its output is either 0 (no photon arrived) or 1 (photon arrived). As a consequence, a SPAD pixel cannot measure a continuous intensity value. To achieve non-binary pixel values with SPAD sensors, “photon counting” may be applied which relates to counting of the photons hitting a pixel (or areas of the sensor) over time.

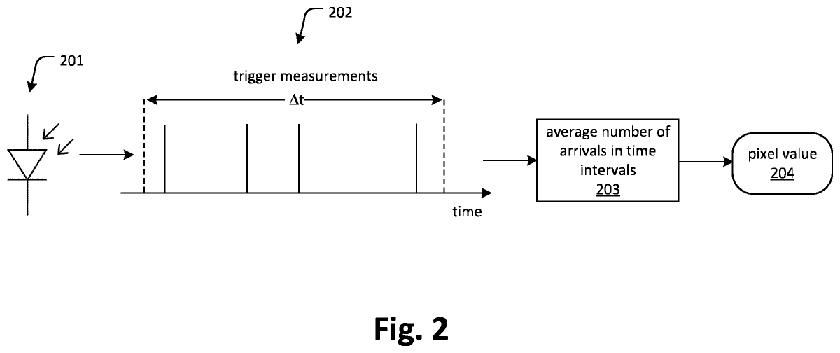

FIG. 2 schematically provides an example of a process of determining a pixel value according to a “photon counting” approach. At 201 photons create electron-hole pair on a SPAD pixel and trigger respective avalanche effects that result in macroscopic currents flowing through the diode corresponding to the photon arrivals according to Poisson statistics. At 202, the number of avalanches produced by the SPAD pixel within predetermined time intervals Δt are counted to determine respective numbers of arrivals for the time intervals Δt. At 203, the average number of arrivals is determined based on the number of avalanches produced by the SPAD pixel within the predetermined time intervals Δt. At 204, a pixel value is obtained from the average number of arrivals obtained at 203.

As an alternative to “photon counting”, the previously proposed solutions adopt a “spatial counting” approach: the number of SPAD pixel with the status 0 and 1 are counted over a given area of the sensor and these values 0 and 1 are converted into an intensity for the considered area. This approach reduced the effective resolution, as multiple SPAD pixels are used to emulate a single traditional pixel. That is, SPAD sensor permit very high-resolution binary imaging, but this high resolution is sacrificed by spatial counting in order to emulate the continue intensity of traditional pixels, thus limiting the benefits offered by SPAD pixels themselves.

The embodiments described below in more detail relate to providing a giga-pixel image sensor, using SPAD (or other similar technologies), where the intensity per pixel is measured by counting photons arrivals in the time domain, rather than in the spatial one. In particular, the embodiments describe a “counting” or “measuring” of the time that passes between (not necessarily consecutive) photon arrivals at a pixel (or within a larger area of the sensor) and the conversion of these times into intensity signals.

This approach described in the embodiments above allows to take benefit of the high number of pixels, thus for example permitting to support different modalities such as described below with regard to the super-pixel sensor of FIG. 2.

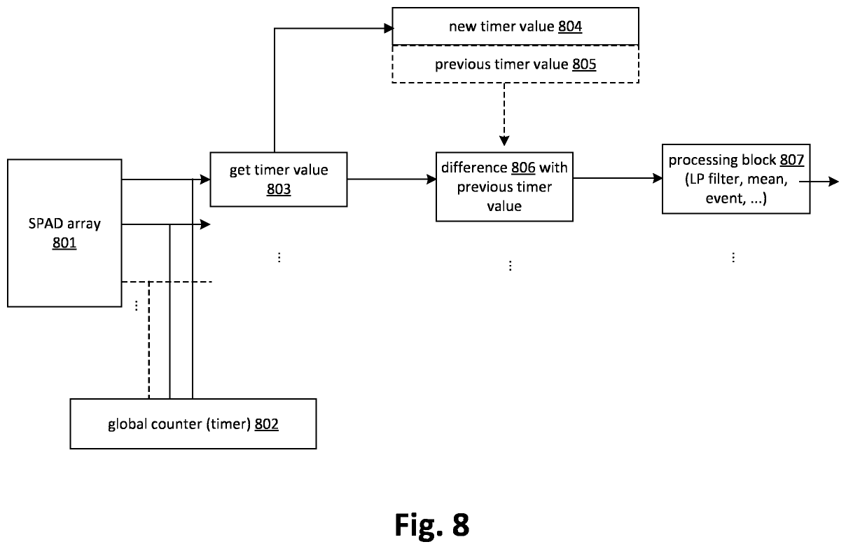

As opposed to traditional “photon counting”, which makes the sensor pixels synchronous, the measuring the time between photon arrivals leads naturally to asynchronous pixels. This technology is for example suitable for Event-Based Vision Sensors (EVS) and could be used, more in general, for highly compact multi-modal sensors. Event-Based Vision Sensors (EVS) are image sensors that use smart pixels that are inspired by the way human eyes work such that they detect both stationary as well as moving objects immediately. This can be used in robotics, mobile devices, mixed reality, automotive and a range of industrial applications. The approach described in the embodiments below may also permit to have a single (global) clock (see 802, 902 and 1002 in FIGS. 8, 9 and 10 below) measuring the time for the whole sensor, rather than a counter at each pixel, with all the advantages that that entails.

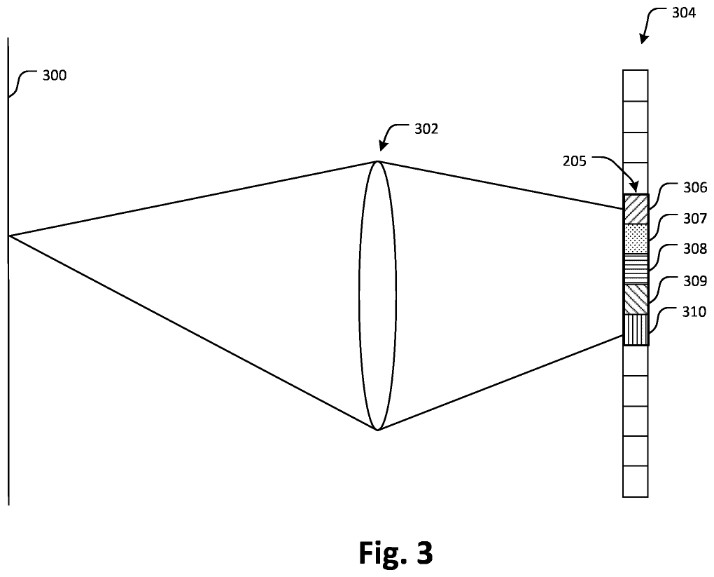

FIG. 3 schematically shows a cross-section of an exemplifying super-pixel sensor. A main lens 302 maps a 3D scene 300 onto a super-pixel sensor 304. The super-pixel sensor 304 comprises multiple super-pixels 305. Each super-pixel 305 is a multiplex pixel which comprises multiple sub-pixels 306, . . . , 210. Each sub-pixel 306, . . . , 210 is allocated to a different task. In the specific example of FIG. 2, the super-pixel 305 comprises five sub-pixels: sub-pixels 306, 307, 308 sense red, green, blue, sub-pixel 309 senses the infrared components of the light and sub-pixel 210 is allocated to range measurements.

For example, considering 4 polarization directions and 16 color channels, it is possible to have a “super-pixel” of 64 sub-pixels (8×8), each with different color and polarization filter. In this setup, due to the limited lens resolution compared to the SPAD sensor, photons arriving in the 8×8 area will be spread over this area and filtered by the different modalities that characterize the 64 sub-pixels as shown in the example depicted in FIG. 2 above. Then, the photons arriving at each sub-pixel will be counted one after the other, in time. Finally, the counting signal at each one of the 64 sub-pixels can be post-processed (e.g., with averaging, but not only) in order to extract the desired signal, depending on the target application.

The processing described in the embodiments below in more detail makes it possible to add more modalities, like ToF (direct and/or indirect). Moreover, due to the intrinsic asynchronous nature of the SPAD sensor, it becomes possible to emulate an event sensor by considering a different post-processing than averaging.

The final measured value of a pixel may for example be derived from a computation, usually average, but it can also be a differentiation followed by averaging or anything else.

The nature of the pixel in this scheme may be asynchronous.

In view of this it becomes possible to realize a pixel computation which triggers events (like in EVS cameras) as soon as certain condition is reached.

The photon counting can happen in different ways, such as: counting arrival time of photons at pixel (or global) level; counting photons at pixel level, for a given time interval; counting photons at pixel level, generating a frame event when a certain percentage of pixels counters are saturated; or counting photons at pixel level until the counter wraps around and then generate a trigger for a global arrival time counter (local average of photons).

Given the giga-pixel resolution and the lens diffraction limit well above this resolution, the proposed architecture can dramatically reduce the compromise between number multi-modalities (color channel, polarization, etc.) and the modality image resolution.

Furthermore, the proposed setup is expected to support event-like functionalities, if required.

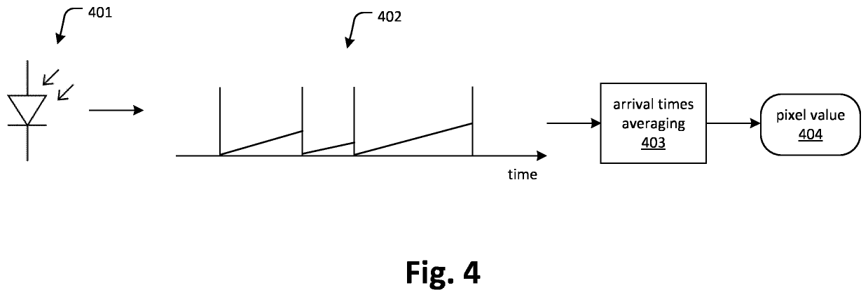

FIG. 4 schematically shows a process of determining a pixel value of a SPAD pixel according to a principle of determining photon arrival times. At 401 photons create electron-hole pair on a SPAD pixel and trigger respective avalanche effects that result in macroscopic currents flowing through the diode corresponding to the photon arrivals according to Poisson statistics. At 402, the avalanches produced by the SPAD pixel are shown in a diagram over time on the horizontal axis. On the vertical axis of the diagram the integrated time is shown as determined by a timer that is reset to zero upon each avalanche occurring. This integrated time corresponds to the arrival time of the photon with respect to the previous event. At 403, the arrival times of the photons are averaged to obtain an average arrival time. Based on this average arrival time, a pixel value 404 is obtained.

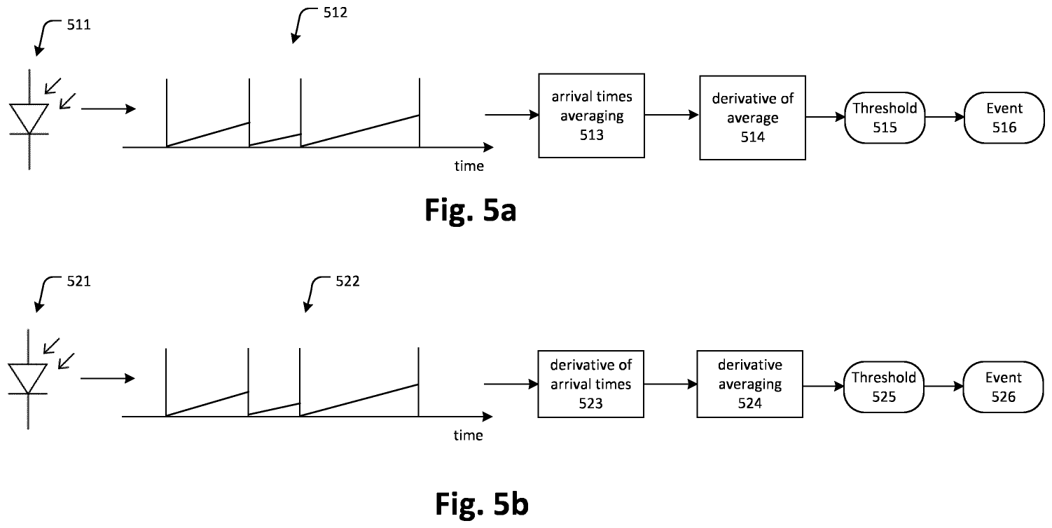

FIG. 5a schematically provides an example of a process of determining an event according to a principle of the embodiments. At 511 photons create electron-hole pair on a SPAD pixel and trigger respective avalanche effects that result in macroscopic currents flowing through the diode corresponding to the photon arrivals according to Poisson statistics. At 512, the avalanches produced by the SPAD pixel are shown in a diagram over time on the horizontal axis. On the vertical axis of the diagram the integrated time is shown as determined by a timer that is reset to zero upon each avalanche occurring. This integrated time corresponds to the arrival time of the photon with respect to the previous avalanche. At 513, the arrival times of the photons are averaged to obtain an average arrival time. At 514, the derivative of the average arrival time is determined. At 405, the derivative of the average arrival time is compared with a predefined threshold. If the derivative of the average arrival time exceeds the threshold, an event 516 is produced.

FIG. 5b schematically provides another example of a process of determining an event according to a principle of the embodiments. At 521 photons create electron-hole pair on a SPAD pixel and trigger respective avalanche effects that result in macroscopic currents flowing through the diode corresponding to the photon arrivals according to Poisson statistics. At 522, the avalanches produced by the SPAD pixel are shown in a diagram over time on the horizontal axis. On the vertical axis of the diagram the integrated time is shown as determined by a timer that is reset to zero upon each avalanche occurring. This integrated time corresponds to the arrival time of the photon with respect to the previous avalanche. At 523, the derivative of the arrival times of the photons is determined. At 524, the derivative of the arrival time is averaged. At 525, the average of the derivative of the arrival time is compared with a predefined threshold. If the average of the derivative of the average arrival time exceeds the threshold, an event 526 is produced.

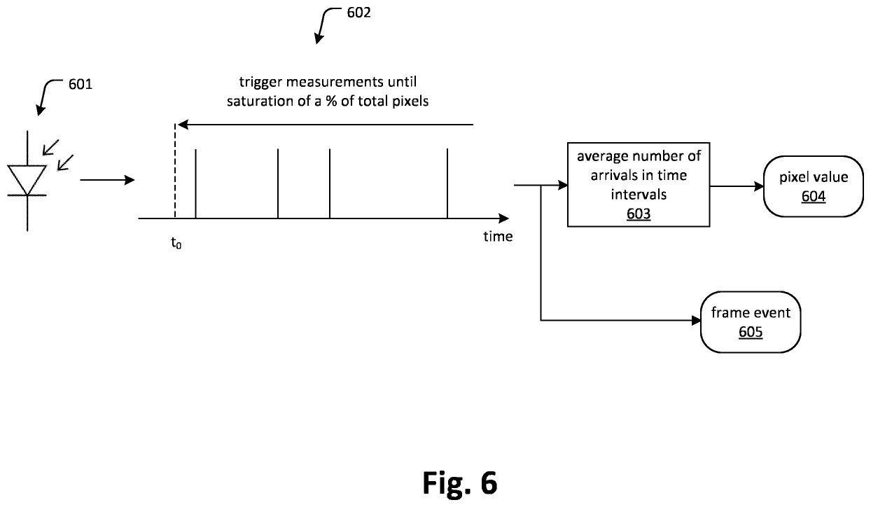

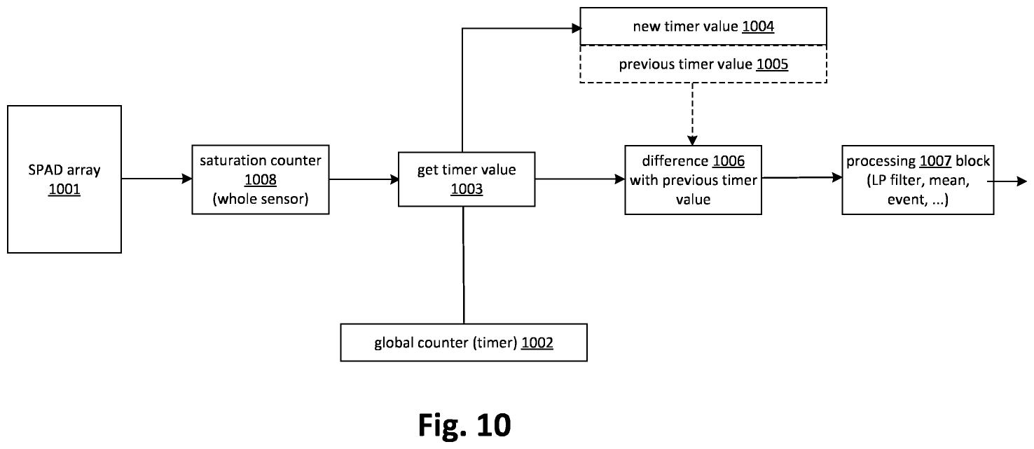

FIG. 6 schematically provides an example of a process of determining a pixel value based on sensor saturation. At 601 photons create electron-hole pair on a SPAD pixel and trigger respective avalanche effects that result in macroscopic currents flowing through the diode corresponding to the photon arrivals according to Poisson statistics. At 602, the number of avalanches produced by the SPAD pixel is counted starting from a predetermined time to until a saturation of a predefined percentage of pixels of the sensor array is achieved (see also saturation counter 1008 in FIG. 10). At 603, the average number of arrivals in the time intervals that are defined by saturation is determined based on the number of avalanches produced by the SPAD pixel counted starting from a predetermined time to until a saturation of a predefined percentage of pixels is achieved. A pixel value 604 is obtained from the average number of arrivals obtained at 603 and a frame event 605 (which controls the frame rate) is triggered after saturation of a predefined percentage of pixels is achieved. Other than the processes shown in FIGS. 5a and 5b, this process of FIG. 6 operates without use of a timer per pixel. The frame in this example rate is variable, depending on the photons arriving.

In the example of FIG. 6 the pixels operate synchronously but the frames are asynchronous (changing frame rate). The events generated at 604 relate to frames.

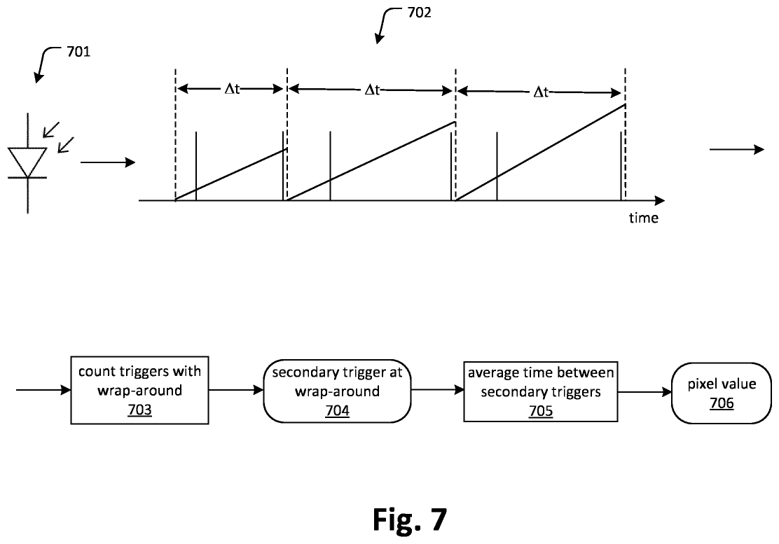

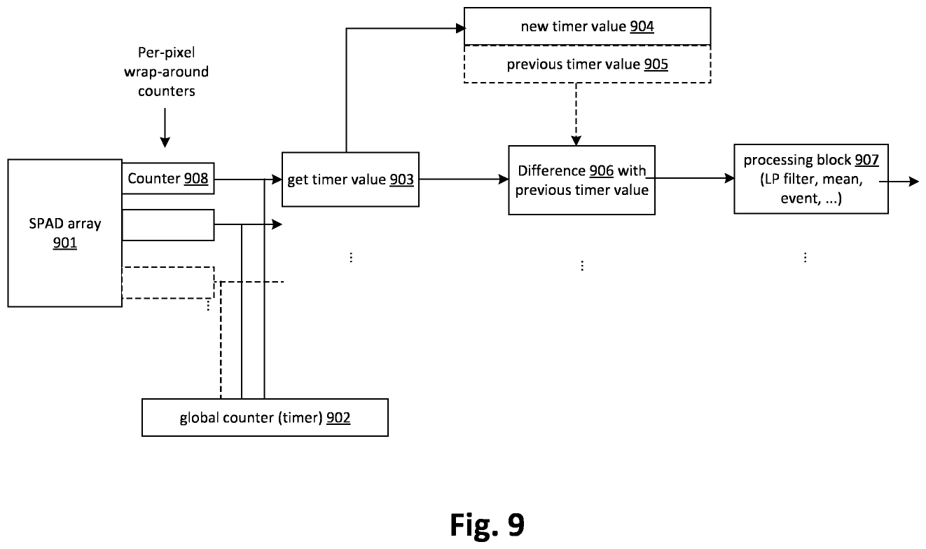

FIG. 7 schematically provides an example of a process of determining a pixel value that is based on per pixel wrap-around counting. At 701 photons create electron-hole pair on a SPAD pixel and trigger respective avalanche effects that result in macroscopic currents flowing through the diode corresponding to the photon arrivals according to Poisson statistics. At 702, the arrivals (avalanches) detected by the SPAD pixel are shown in a diagram over time together with time intervals Δt defined by a pixel individual wrap-around counter (see 908 in FIG. 9). At 703, the avalanches (triggers) produced by the SPAD pixel are counted during time intervals Δt defined by the pixel individual wrap-around counter until a predefined number of avalanches has been detected (in the example of FIG. 7, for sake of simplicity of the drawings, the time intervals Δt end after the second arrival detected by the wrap-around counter and the wrap-around counter is reset to zero). At 704, secondary triggers are produced after wrap-around (when the wrap-around counter reaches the predefined maximal count). At 705, the average time between secondary triggers is obtained (see difference 906 with determining the mean at 907 of in FIG. 9). A pixel value 706 is obtained from the average time of secondary triggers obtained at 705.

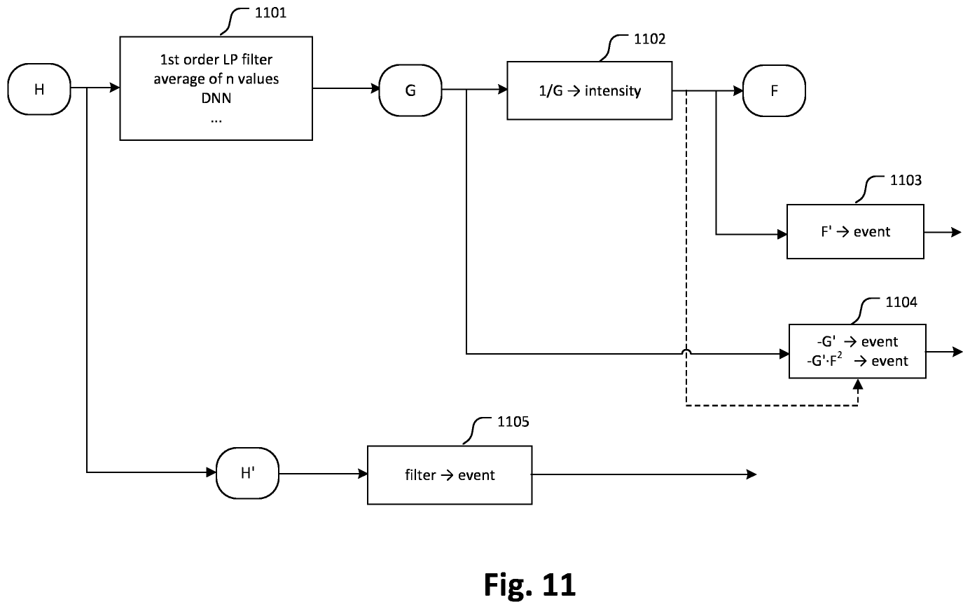

FIG. 8 provides a block diagram that schematically describes an implementation of the process described in FIG. 5b using a global counter (timer) and per pixel memories for storing timer values. In the pixels of a SPAD array 801, photons create electron-hole pairs and trigger respective avalanche effects. A global counter 802 is configured to provide a (global) timer value to each of the pixels of the SPAD array 801. When an avalanche is triggered in a pixel of the SPAD array 801, then at 803, the timer value of the global counter 802 that corresponds to the avalanche occurrence is obtained. At 804, the timer value obtained at 803 that corresponds to the avalanche occurrence is stored in a memory as a new timer value 804. The memory also stores a previous timer value 805 that corresponds to a previous avalanche. At 806 the difference between the new timer value 804 and the previous timer value 805 is obtained. This difference 806 which corresponds to the derivative of the arrival times of photons arriving on the pixel is passed to a processing block 807 as an arrival time. The processing block 807 performs further processing on the arrival time, respectively on multiple such arrival times obtained from subsequent avalanches occurring in this pixel. Such processing may comprise applying an LP filter (see 1101 in FIG. 11), determining the mean of the arrival times (see 524 in FIG. 5b; 1101 in FIG. 11), and/or determining events (see 525 and 526 in FIG. 5b; 1103, 1104, 1105 in FIG. 11). As indicated by the arrows emerging from SPAD array 801 in FIG. 8, the obtaining the timer value 803, the storing of the timer value 804, the storing of a previous timer value 805, the determining of a difference 806 with the previous timer value 805, and the processing 807 is foreseen for each of the pixels of SPAD array 801.

The global counter 802 of FIG. 8 may for example be configured to increment at a speed of 1 MHz, thus providing a time resolution of 1 μs.

FIG. 9 provides a block diagram that schematically describes an implementation of the process described in FIG. 5b using a global counter (timer) and per pixel wrap-around counters. In the pixels of a SPAD array 901, photons create electron-hole pairs and trigger respective avalanche effects. A global counter 902 is configured to provide a (global) timer value to each of the pixels of the SPAD array 901. When an avalanche is triggered in the pixel of the SPAD array 901, then a wrap-around counter 908 is incremented. When the wrap-around counter 908 reaches a predefined maximal count (e.g. 20), then, at 903, the timer value of the global counter 902 is obtained (see secondary trigger 704 of FIG. 7). At 904, the timer value of the global counter obtained at 903 is stored in a memory as a new timer value 904. The memory also stores a previous timer value 905 that corresponds to a previous time at which the wrap-around counter 908 reached the predefined count. At 906 the difference between the new timer value 904 and the previous timer value 905 is obtained. This difference 906 which is proportional to the average arrival time of photons arriving on the pixel is passed to a processing block 907. If divided by the maximal count that is predefined by wrap-around counter 908, then difference 906 corresponds to the average arrival time of the photons (see 513 in FIG. 5a). The processing block 907 performs further processing on the average arrival time, respectively on multiple such average arrival times obtained from subsequent avalanches occurring in this pixel. Such processing may comprise applying an LP filter (see 1101 in FIG. 11), determining the mean of the arrival times (see 524 in FIG. 5b; 1101 in FIG. 11), and/or determining events (see 525 and 526 in FIG. 5b; 1103, 1104, 1105 in FIG. 11). As indicated by the arrows emerging from SPAD array 901 in FIG. 8, the wrap-around counter 908, obtaining the timer value 903, the storing of the timer value 904, the storing of a previous timer value 905, the determining of a difference 906 with the previous timer value 905, and the processing 907 is foreseen for each of the pixels of SPAD array 901.

FIG. 10 provides a block diagram that schematically describes an alternative implementation using a global counter (timer) and a saturation counter. In the pixels of a SPAD array 1001, photons create electron-hole pairs and trigger respective avalanche effects. A global counter 1002 is configured to provide a (global) timer value to each of the pixels of the SPAD array 1001. When an avalanche is triggered in any pixel of the SPAD array 1001, then a saturation counter 1008 which is provided for the whole sensor is incremented. When the saturation counter 1008 reaches a predefined maximal count (e.g. 1000) which corresponds to a saturation of a predefined percentage of pixels of the sensor, then, at 1003, the timer value of the global counter 902 is obtained. At 1004, the timer value obtained at 1003 is stored in a memory as a new timer value 1004. The memory also stores a previous timer value 1005 that corresponds to a previous avalanche. At 1006 the difference between the new timer value 1004 and the previous timer value 1005 is obtained. This difference 1006 which corresponds to the current saturation time of the sensor is passed to a processing block 1007. The processing block 1007 performs further processing on the saturation time, respectively on multiple such arrival times obtained from subsequent avalanches occurring in this pixel. Such processing may comprise applying an LP filter (see 1101 in FIG. 11), determining the mean of the saturation times (see 524 in FIG. 5b; 1101 in FIG. 11), and/or determining events (see 525 and 526 in FIG. 5b; 1103, 1104, 1105 in FIG. 11). As indicated by the arrows emerging from SPAD array 1001 in FIG. 8, the obtaining the timer value 1003, the storing of the timer value 1004, the storing of a previous timer value 1005, the determining of a difference 1006 with the previous timer value 1005, and the processing 1007 is foreseen for each of the pixels of SPAD array 1001. Accordingly, in the implementation example of FIG. 8 a memory for storing timer values is required for each pixel of the SPAD array 1001.

FIG. 11 shows an example of processing performed in processing block for the processing of photon arrival times. A total number n of arrival times H as described in the implementation of FIG. 8 (or alternatively average arrival times as described in the implementation of FIG. 9 or saturation times as described in the implementation of FIG. 10) are provided to the processing block as described in the implementations of FIG. 8, 9, or 10. At 1101, the n arrival times are processed to determine an arrival time G. The mapping of the arrival times H to the arrival time G may for example be realized by averaging the n arrival times H, by applying an LP filter on the arrival times H, or by using a DNN to map the arrival times H to the arrival time G. At 1102, the arrival time G as obtained at 1101 is inverted to obtain an intensity F. Several alternative event generation options are provided that operate based on arrival times H, arrival time G, intensity F or derivatives thereof. For example, at 1103 the derivative F′ of the intensity F is determined and events are created based on the derivative F′ of the intensity. At 1104 the negative derivative -G′ of the arrival time G is determined and events are created based on the negative derivative -G′. Still further, at 1104 events are created based on the product of intensity F and the negative derivative -G′ of the arrival time G. At 1105 further events are created based on the derivative H′ of the arrival times H.

### Implementation

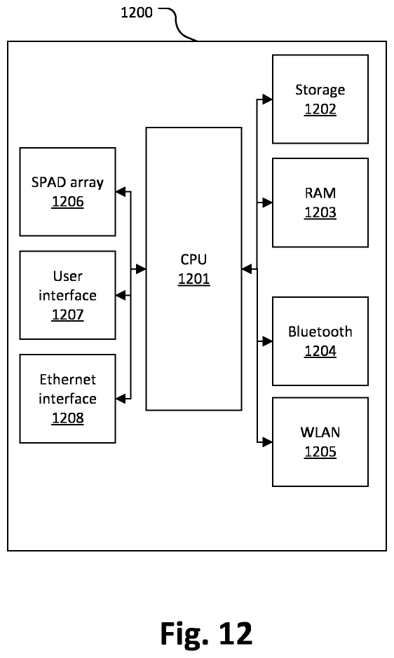

FIG. 12 schematically describes an embodiment of an electronic device that can implement the processes of the embodiments described above. The electronic device 1200 comprises a CPU 1201 as processor. The electronic device 1200 further comprises an SPAD array 1206 (e.g. the SPAD array 801, 901, 1001 described in the embodiments above) connected to the processor 1201. The processor 1201 may for example implement the processing described in FIG. 11 above. The electronic device 1200 further comprises a user interface 1207 that is connected to the processor 1201. This user interface 1207 acts as a man-machine interface and enables a dialogue between an administrator and the electronic system. For example, an administrator may make configurations to the system using this user interface 1207. The electronic device 1200 further comprises a Bluetooth interface 1204, a WLAN interface 1205, and an Ethernet interface 1208. These units 1204, 1205 act as I/O interfaces for data communication with external devices. For example, video cameras with Ethernet, WLAN or Bluetooth connection may be coupled to the processor 1201 via these interfaces 1204, 1205, and 1208. The electronic device 1200 further comprises a data storage 1202, and a data memory 1203 (here a RAM). The data storage 1202 is arranged as a long-term storage, e.g. for storing the algorithm parameters for one or more use-cases, for recording sensor data obtained from the sensor 1206, or the like. The data memory 1203 is arranged to temporarily store or cache data or computer instructions for processing by the processor 1201.

It should be noted that the description above is only an example configuration. Alternative configurations may be implemented with additional or other sensors, storage devices, interfaces, or the like.

### Multiple Photon Capture Problem

If photons arrive faster than the resolution of the timer, than a double photon capture problem may occur. In the embodiments described above, this double photon capture problem may be solved by applying a correction algorithm.

The correction algorithm described below provides a missing photons correction that is based on knowledge about the statistical curve known to correct the signal.

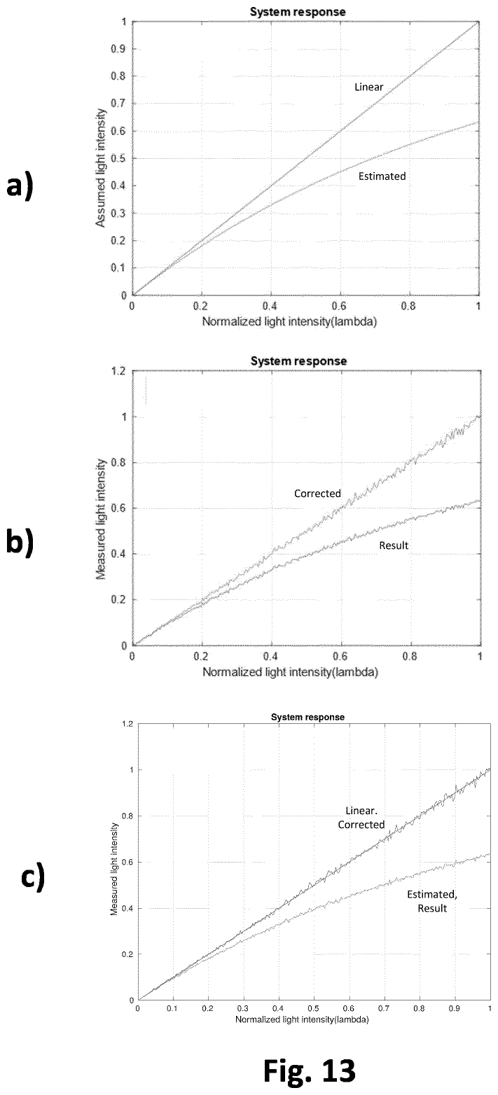

FIGS. 13a, b, c show in a diagram the measured light intensity over the normalized light intensity. “Estimated” and “corrected” signals are shown together with “linear” signal and “result”. The result and the corrected signal relate to a processing of average arrival times for 10000 clock cycles with correction (ramp). The “estimated” signal relates to the result of the statistical model taking into account the fact that multiple photon arrivals can happen at once. The purpose of “estimated” is to show that this matches the simulation. The “linear” signal represents the true signal. It goes into the correction in the sense that this is the “target” that is expected to be achieve.

Under Poisson assumptions, missing photons result in binomial statistics.

The corrected intensity is obtained according to:

$${I}_{c orrected} = - log ( 1 - {I}_{input} )$$

where I_{corrected} is the corrected signal as obtained by the correction algorithm and Iᵢₙₚᵤₜ is the result, i.e. the measurements from the sensor.

### Simulation Results

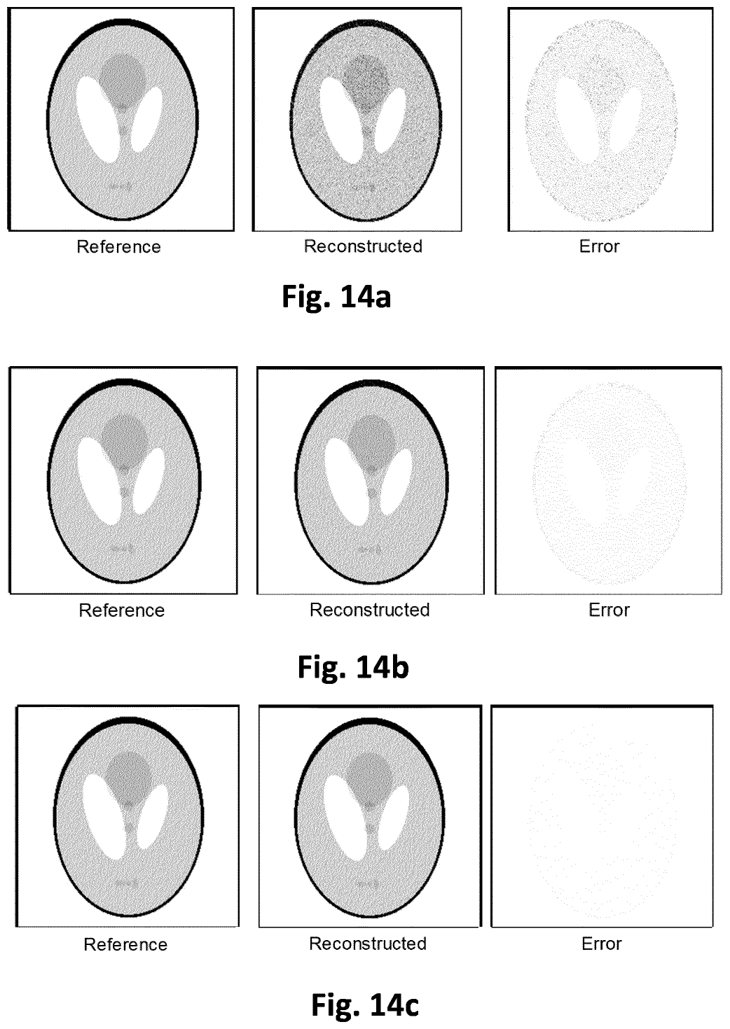

FIGS. 14a, b, c show simulation results for synchronous pixels as obtained by the “photon counting” approach described with regard to FIG. 2 above.

FIG. 14a shows a reference image, a reconstructed image and an error image for an average of 10 photons arrival times, taking an arrival time of 10 photons per pixel. FIG. 14b shows a reference image, a reconstructed image and an error image for an average of 100 photons arrival times, taking an arrival time of 1000 photons per pixel. FIG. 14c shows a reference image, a reconstructed image and an error image for an average of 1000 photons arrival times, taking an arrival time of 10 photons per pixel. It can be seen from FIGS. 14a, b, c, that the error gets larger if there are less photon arrival times contributing

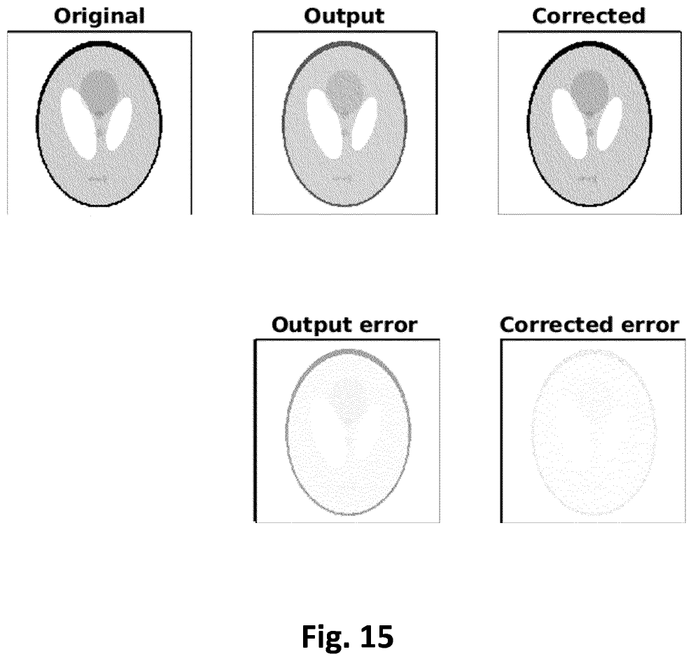

FIG. 15 shows an original image, an output image, a corrected image, an output error, and a corrected error for filtered arrival times for 10000 clock cycles with 1^{st} order IIR and correction. The corrected image has been obtained according to the process described with regard to FIG. 8 above in which a global counter is applied. Computation has been stopped after 10000 clock cycles. This is an example of asynchronous pixels. It can be seen from FIG. 15 that the corrected error is significantly reduces as compared to the output error without correction.

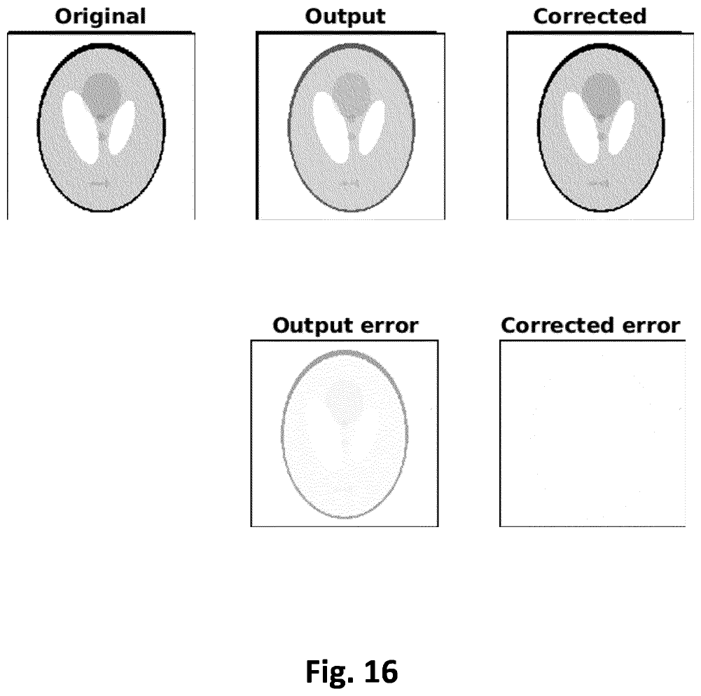

FIG. 16 shows an original image, an output image, a corrected image, an output error, and a corrected error for average arrival times for 10000 clock cycles with correction. The corrected image has been obtained according to the process described with regard to FIG. 8 above in which a global counter is applied. Computation has been stopped after 10000 clock cycles. This is an example of asynchronous pixels. It can be seen from FIG. 16 that the corrected error is significantly reduced as compared to the output error without correction.

It should be recognized that the embodiments describe methods with an exemplary ordering of method steps. The specific ordering of method steps is however given for illustrative purposes only and should not be construed as binding.

Please note that the division of the control XY into units XY and XY is only made for illustration purposes and that the present disclosure is not limited to any specific division of functions in specific units. For instance, the control XY could be implemented by a respective programmed processor, field programmable gate array (FPGA) and the like.

A method for controlling an electronic device, such as mobile terminal XY discussed above, is described in the following and under reference of Fig. XY. The method can also be implemented as a computer program causing a computer and/or a processor, such as processor XY discussed above, to perform the method, when being carried out on the computer and/or processor. In some embodiments, also a non-transitory computer-readable recording medium is provided that stores therein a computer program product, which, when executed by a processor, such as the processor described above, causes the method described to be performed.

All units and entities described in this specification and claimed in the appended claims can, if not stated otherwise, be implemented as integrated circuit logic, for example on a chip, and functionality provided by such units and entities can, if not stated otherwise, be implemented by software.

In so far as the embodiments of the disclosure described above are implemented, at least in part, using software-controlled data processing apparatus, it will be appreciated that a computer program providing such software control and a transmission, storage or other medium by which such a computer program is provided are envisaged as aspects of the present disclosure.

Note that the present technology can also be configured as described below.

(1) An electronic device comprising circuitry configured to determine times that pass between photon arrivals at a pixel (401; 511; 521) of an imaging sensor (801; 901; 1001) or within larger areas of the imaging sensor, and to convert these times into intensity signals (404; 604; 706).

(2) The electronic device of (1), wherein the circuitry is configured to determine photon arrival times at the pixel of the imaging sensor (801; 901; 1001).

(3) The electronic device of (1) or (2), wherein the circuitry is configured to perform processing of the arrival time.

(4) The electronic device of (3), wherein the processing of the arrival time comprises performing arrival time averaging (403; 513), applying an LP filter, and/or determining events.

(5) The electronic device of any one of (1) to (4), wherein the circuitry is configured to determine (514) derivatives of arrival time averages.

(6) The electronic device of any one of (1) to (5), wherein the circuitry is configured to determine (523) derivatives of arrival times.

(7) The electronic device of any one of (1) to (6), wherein the circuitry is configured to determine (524) averages of derivatives of arrival times.

(8) The electronic device of any one of (1) to (7), wherein the circuitry is configured to determine intensity signals (404; 604; 706) for the pixels of the imaging sensor (801; 901; 1001) based on sensor saturation (603, 1008).

(9) The electronic device of any one of (1) to (8), wherein the circuitry is configured to determine intensity signals (404; 604; 706) for the pixel of the imaging sensor (801; 901; 1001) based on per pixel wrap-around counting (702, 704; 903).

(10) The electronic device of any one of (1) to (9), comprising a global counter (802, 902 and 1002) configured to measure the time for the whole sensor.

(11) The electronic device of any one of (1) to (10), comprising a global counter (802, 902 and 1002) and per pixel memories for storing timer values (804, 805; 904, 905; 1004; 1005).

(12) The electronic device of any one of (1) to (11), comprising a global counter (902) and per pixel wrap-around counters (908).

(13) The electronic device of any one of (1) to (12), comprising a global counter (1002) and a saturation counter (1008).

(14) The electronic device of any one of (1) to (13), wherein the imaging sensor (801; 901; 1001) uses SPAD technologies.

(15) The electronic device of (14), wherein the imaging sensor (801; 901; 1001) is a giga-pixel image sensor.

(16) The electronic device of any one of (1) to (15), in which the pixels (401; 511; 521) are synchronous pixels.

(17) The electronic device of any one of (1) to (16), in which the imaging sensor (801; 901; 1001) is configured to support different modalities.

(18) The electronic device of any one of (1) to (17), in which the imaging sensor (801; 901; 1001) is configured to be applied in Event-Based Vision Sensors (EVS).

(19) A method comprising determining times that pass between photon arrivals at a pixel (401; 511; 521) of an imaging sensor (801; 901; 1001) or within larger areas of the imaging sensor, and to convert these times into intensity signals (404; 604; 706).

(20) A computer program comprising instructions which are configured to, when executed on a processor, perform the method of (19).

(21) A non-transitory computer-readable recording medium that stores therein a computer program product, which, when executed by a processor, causes the method according to (19) to be performed.

1. An electronic device comprising circuitry configured to determine times that pass between photon arrivals at a pixel of an imaging sensor or within larger areas of the imaging sensor, and to convert these times into intensity signals.

2. The electronic device of claim 1, wherein the circuitry is configured to determine photon arrival times at the pixel of the imaging sensor.

3. The electronic device of claim 1, wherein the circuitry is configured to perform processing of the arrival time.

4. The electronic device of claim 3, wherein the processing of the arrival time comprises performing arrival time averaging, applying an LP filter, and/or determining events.

5. The electronic device of claim 1, wherein the circuitry is configured to determine derivatives of arrival time averages.

6. The electronic device of claim 1, wherein the circuitry is configured to determine derivatives of arrival times.

7. The electronic device of claim 1, wherein the circuitry is configured to determine averages of derivatives of arrival times.

8. The electronic device of claim 1, wherein the circuitry is configured to determine intensity signals for the pixels of the imaging sensor based on sensor saturation.

9. The electronic device of claim 1, wherein the circuitry is configured to determine intensity signals for the pixel of the imaging sensor based on per pixel wrap-around counting.

10. The electronic device of claim 1, comprising a global counter configured to measure the time for the whole sensor.

11. The electronic device of claim 1, comprising a global counter and per pixel memories for storing timer values.

12. The electronic device of claim 1, comprising a global counter and per pixel wrap-around counters.

13. The electronic device of claim 1, comprising a global counter and a saturation counter.

14. The electronic device of claim 1, wherein the imaging sensor uses SPAD technologies.

15. The electronic device of claim 14, wherein the imaging sensor is a giga-pixel image sensor.

16. The electronic device of claim 1, in which the pixels are synchronous pixels.

17. The electronic device of claim 1, in which the imaging sensor is configured to support different modalities.

18. The electronic device of claim 1, in which the imaging sensor is configured to be applied in Event-Based Vision Sensors (EVS).

19. A method comprising determining times that pass between photon arrivals at a pixel of an imaging sensor or within larger areas of the imaging sensor, and to convert these times into intensity signals.

20. A computer program comprising instructions which are configured to, when executed on a processor, perform the method of claim 19.
